(19) United States
(12) Patent Application Publication
(10) Pub. No.: US 2018/0331486 A1
(43) Pub. Date: Nov. 15, 2018

(54) A PACKAGING STRUCTURE OF LASER AND GRATING COUPLER AND ITS METHOD

(71) Applicant: Wuhan Telecommunication Devices Co., Ltd., Wuhan City, Hubei Province (CN)

(72) Inventors: Shiyu LI, Wuhan City, Hubei Province (CN); Di ZHANG, Wuhan City, Hubei Province (CN); Shenglei HU, Wuhan City, Hubei Province (CN); Shaohua YU, Wuhan City, Hubei Province (CN)

(73) Assignee: Wuhan Telecommunication Devices Co., Ltd., Wuhan City, Hubei Province (CN)

(21) Appl. No.: 15/772,336

(22) PCT Filed: Dec. 28, 2015
(86) PCT No.: PCT/CN2015/099207

§ 371 Date: Apr. 30, 2018

(30) Foreign Application Priority Data
Oct. 30, 2015 (CN) 201510730699.1

(51) Int. Cl. H01S 3/00; H01S 5/022; H01S 5/026; G02B 6/42; G02B 6/34

(52) U.S. Cl. CPC H01S 3/0071; H01S 5/02288; G02B 6/34; H01S 5/0261; G02B 6/4214; H01S 5/02268

(57) ABSTRACT

The present invention provides a packaging structure of a laser and a grating coupler and its method, wherein: the packaging structure of a laser and a grating coupler comprises a laser unit, a collimating lens, an isolator and a reflecting prism that are provided on a silicon photonic chip; the silicon photonic chip comprises a first electrode, a first marker, a second marker, a grating coupler and a waveguide layer that are provided on a surface plane; the laser unit comprises a transition substrate and a laser; and the collimating lens comprises a first lens and a second lens, the first lens stands perpendicularly to the surface plane, and the second lens is provided on the surface plane by aligning with the second marker, so that the grating coupler is positioned in a central area of a principal axis of an optical path of the second lens, and the isolator is installed at a surface plane that is between the first lens and the second lens, so that a divergent light outputted by the laser is collimated by the first lens, passes through the isolator, becomes incident to the reflecting prism, is angularly deflected by the reflecting prism, and is converged by the second lens, wherein a convergence point is located at a surface of the grating coupler. Such a constitution solves the technical problem of accurate aligning and packaging, and simplies the manufacturing and improves the product yield.

### TECHNICAL FIELD

The present invention provides a silicon photonic integrated device, and particularly to a packaging structure of a laser and a grating coupler and its method.

### BACKGROUND ART

Silicon monolithic integrated optoelectronic chips become presently an international research hot spot. Silicon optoelectronic integration technology is to monolithically integrate a waveguide/modulator, a photodetector and a driver circuit and a receiver circuit, that is, to integrate optical elements and electrical elements on a single chip, and all of the devices are fabricated by using standard integrated circuit process which is a mature process. The advantages of the silicon monolithic integrated optoelectronic chip is low cost and small size, and this chip is suitable for the application in short distance optical communications such as data centers.

Although silicon materials can be used to fabricate most of the optical devices and electrical devices in fiber optical communication, because silicon is an indirect semiconductor material, whose extreme values of the conduction band and valence band correspond to different wave vectors, which has very low probability of radiative recombination, and there are two strong non-radiative transition processes: auger recombination and free carrier absorption. Therefore, silicon materials cannot be used to fabricate laser elements. At present, there are many researches to overcome such defect of the silicon, for example, impurity doping, quantum restriction, silicon germanium alloy and so on. However, the solution which can sufficiently satisfy the performance requirements have not be seen, so in the silicon monolithic integrated optoelectronic chips, A simple and feasible approach to realize the effect of light source in silicon integrated optoelectronic chip is the external hybrid integration of group III-V lasers on silicon. Therefore, how to improve the coupling efficiency and simplify the coupling process need to be solved.

### Technical Problems

In order to solve the above technical problems, the major object of the present invention is to provide a packaging structure of a laser and a grating coupler and to provide a packaging method of a laser and a grating coupler.

### SUMMARY OF THE INVENTION

In order to reach the above object, the present invention applies the following technical solution: a packaging structure of a laser and a grating coupler, comprising a laser unit, a collimating lens, an isolator and a reflecting prism that are provided on a silicon photonic chip, wherein: the silicon photonic chip comprises a surface plane and a first electrode, a first marker, a second marker, a grating coupler and a waveguide layer that are sequentially provided on the surface plane; the laser unit comprises a transition substrate and a laser, and further comprises a second electrode that is exposed on the top surface of the transition substrate; and the collimating lens comprises a first lens and a second lens, wherein: the first lens stands perpendicularly to the surface plane with an optical path aligning with the laser, and the second lens is provided on the surface plane by aligning with the second marker, so that the grating coupler is positioned in a central area of a principal axis of an optical path of the second lens, and the isolator is installed at a surface plane that is between the first lens and the second lens, so that a divergent light that is outputted by the laser is collimated by the first lens, passes through the isolator, becomes incident to the reflecting prism, is angularly deflected by the reflecting prism, and is converged by the second lens, wherein a convergence point is located at a surface of the grating coupler.

Preferably in the present embodiment, a solder is provided on the top surface of the transition substrate, wherein the solder is provided adjacent to a right side of the top surface, and is electrically connected to the second electrode, and the top surface that is adjacent to the solder is provided with a third marker.

Preferably in the present embodiment, the transition substrate is installed on the surface plane by aligning with the first marker, and the laser is fixed to the top surface by the solder when aligning with the third marker.

Preferably in the present embodiment, the transition substrate is formed by silicon, aluminum nitride and/or aluminum oxide.

In order to reach the above object, the present invention applies the following technical solution: a packaging method of a laser and a grating coupler, comprising:

Firstly, fabricating the second electrode, a solder and the third marker on the transition substrate, and after the laser is accurately aligned with the third marker, pasting the laser to the transition substrate by the solder, wherein a top layer of the laser has a top layer electrode, and the top layer electrode is connected to the second electrode by wire bonding;

Secondly, fabricating the first marker for the aligning with the transition substrate and the second marker for the accurate aligning during the placing of the second lens on the surface plane of the silicon photonic chip, wherein the second lens is directly pasted to the silicon photonic chip, in order to contact a focal plane of the second lens with the silicon photonic chip; and by the effect of position assisting of the second marker, during the aligning and pasting of the second lens, the grating coupler is located in the central area of the principal axis of the optical path of the second lens.

Preferably in the present embodiment, the first lens is on the silicon photonic chip the first lens can be shifted to adjusted the position on the silicon photonic chip, so that the lights outputted by the laser collimated to become parallel light, and then the first lens and the silicon photonic chip are solidified by filling ultraviolet adhesive or thermosetting adhesive between the both.

Preferably in the present embodiment, an isolator is located between the first lens and the reflecting prism, the reflecting prism is fixed to the surface plane, an inclined reflecting end surface of the reflecting prism is located above the second lens, the reflecting prism couples parallel light beams by the second lens into the grating coupler, and finds the optimum coupling efficiency by finely tuning the position of the second lens, and then the second lens is solidified by filling ultraviolet adhesive or thermosetting adhesive.

Preferably in the present embodiment, an optimum coupling efficiency of the grating coupler is obtained by adjusting the second lens and by varying an angle of the reflecting prism, wherein: an angle of a light beam incident to the grating coupler from the reflecting prism is between 30° and 60°.

Preferably in the present embodiment, the transition substrate is pasted by aligning with the first marker and then solidified by filling ultraviolet adhesive or thermosetting adhesive, and simultaneously the second electrode and the first electrode are electrically connected by wire bonding, so that the laser and the silicon photonic chip are electrically connected.

Preferably in the present embodiment, the ultraviolet adhesive or thermosetting adhesive is a transparent adhesive, and the adhesive solidified on the packaging structure of a laser and a grating coupler is transparent to lights of wavelength of 1.2 μm to 1.6 μm.

### Advantageous Effects

The present invention, by employing processes such as photoetching aligning and flip chip bonding, ensures the pasting accuracy and realizes high efficiency coupling. The particular presentations are:

1. The present invention has a simple structure, which facilitates realizing the mass production of hybrid integrated chips;

2. The present invention has isolation effect to echo signals, which prevents the instability of the performance of the laser that is caused by reflected lights; and

3. The present invention realizes the mode field matching of the light beam inputted into the grating coupler by double lenses converting the light beam, thereby reducing the coupling loss.

### BRIEF DESCRIPTION OF THE DRAWINGS

FIG. 1 is the schematic diagram of the assembled structure of the present embodiment.

FIG. 2 is the structural schematic diagram of the surface plane of the silicon photonic chip in FIG. 1.

FIG. 3 is the structural schematic diagram of the top surface of the transition substrate in FIG. 1.

FIG. 4 is the simplified schematic diagram of the principle of operation of the present embodiment.

### DETAILED DESCRIPTION OF THE INVENTION

The present invention will be described in further details below with reference to the drawings and the special embodiments. Examples of the embodiments are shown in the drawings, wherein the same or similar reference numbers represent the same or similar elements or elements having the same or similar functions from beginning to end. The following embodiments illustrated with reference to the drawings are exemplary, are merely intended to explain the technical solutions of the present invention, and should not be understood as a limitation to the present invention.

In the description of the present invention, the orientation or position relations indicated by the terms “inside”, “outside”, “longitudinal”, “lateral”, “upper”, “lower”, “top”, “bottom”, “front”, “back”, “left”, “right” and so on are on the basis of the orientation or position relations that are shown by the drawings, are merely intended to facilitate the describing of the present invention, rather than requiring the present invention to be manufactured or operated in the specific orientations, and thus should not be understood as a limitation to the present invention.

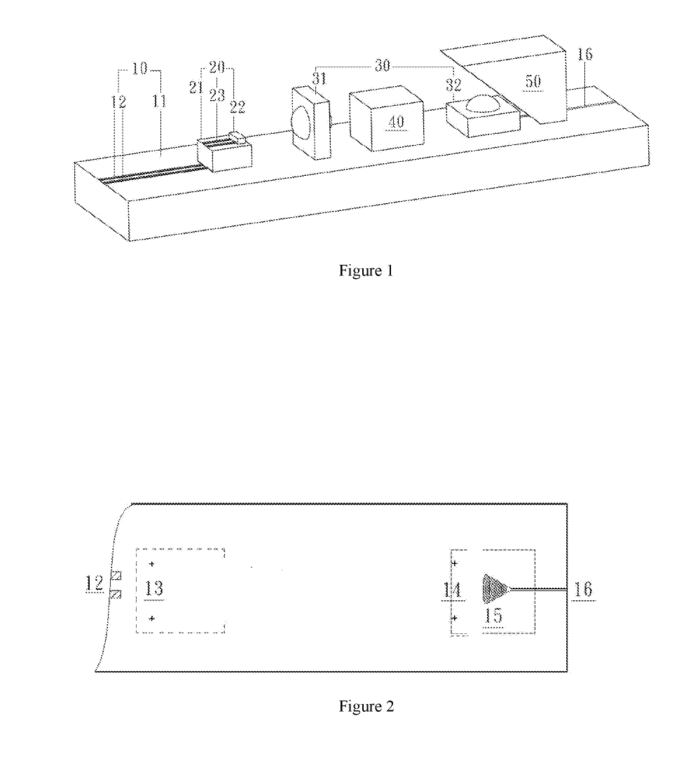

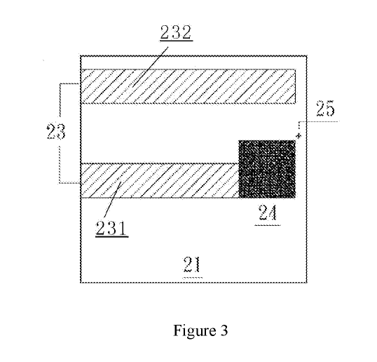

Referring to FIG. 1, FIG. 2 and FIG. 3, the present invention provides a packaging structure of a laser and a grating coupler. FIG. 1 includes a laser unit 20, a collimating lens 30, an isolator 40 and a reflecting prism 50 that are provided on a silicon optoelectronic chip 10 (hereafter referred to as simply “silicon photonic chip”), wherein:

the silicon photonic chip 10 present the shape of a rectangular plate, and comprises a surface plane 11, and a first electrode 12, a first marker 13, a second marker 14, a grating coupler 15 and a waveguide layer 16 that are sequentially (from left to right) provided on the surface plane 11 (as shown in FIG. 2); and

the laser unit 20 comprises a transition substrate 21 and a laser 22, and further comprises a second electrode 23 that is exposed on the top surface (not labeled) of the transition substrate 21. As shown in FIG. 3, the top surface (adjacent to the right side) of the transition substrate 21 is further provided with a solder 24 that is connected to the second electrode 23, and is provided with a third marker 25 that is adjacent to the solder 24. In the present embodiment, the transition substrate 21 is installed on the surface plane 11 by aligning with the first marker 13, and the laser 22 is fixed to the top surface by the solder 24 when aligning with the third marker 25. In that, the second electrode 23 comprises a third sub-electrode 231 and a fourth sub-electrode 232, wherein what is connected to the solder 24 is the third sub-electrode 231, the solder 24 is used to solder the cathode of the laser unit 20, and the fourth sub-electrode 232 is connected to the anode of the laser unit 20 by wire bonding.

The collimating lens 30 (as shown in FIG. 1) comprises a first collimating lens and a second collimating lens (hereafter referred to as simply “first and second lenses”) 31, 32, wherein: the first lens 31 stands particularly to the surface plane 11 with its optical path aligning with the laser 22, and the second lens 32 is provided on the surface plane 11 by aligning with the second marker 14 (horizontally), so that the grating coupler 15 is positioned in the central area of the principal axis of the optical path of the second lens 32.

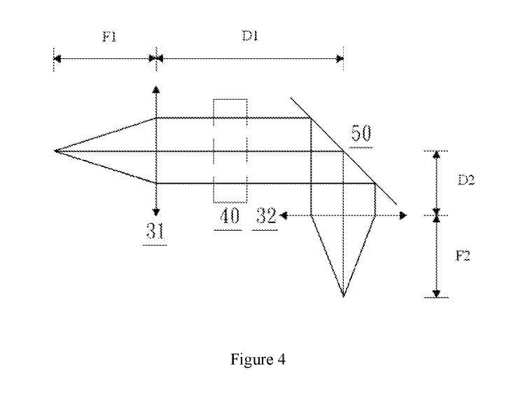

The isolator 40 (as shown in FIG. 1) is installed at the surface plane 11 and is between the first and second lens 31, 32, so that the diffused lights that are outputted by the laser 22 are collimated by the first lens 31 to become parallel light, then pass through the isolator 40, become incident to the reflecting prism 50, are angularly deflected by the reflecting prism 50 (as shown in FIG. 1 and FIG. 4), and are converged by the second lens 32, wherein the convergence point is located at the end surface of the second lens 32, that is, the surface of the grating coupler 15.

Referring to FIG. 1 and FIG. 2 to FIG. 4, the present invention provides a method of the packaging structure of a laser and a grating coupler, comprising:

fabricating the second electrode 23 (for example, a metal electrode of the transmission line type), the solder 24 (for example, a preset solder area where the laser 22 can be adhesive bonded integrally by surface adhesive bonding technique) and the third marker 25 (for example, a metal alignment marker) on the transition substrate 21 (made of materials that have good heat-conducting property, such as silicon, aluminum nitride and aluminum oxide); and

after the laser 22 is accurately aligned with the third marker 25, pasting the laser 22 to the transition substrate 21 by the solder 24, by heating to melt the solder, to integrate the bottom of the laser 22 and the top surface (not labeled) by solidification, wherein the top layer of the laser 22 is provided with a top layer electrode, and the top layer electrode is connected to the fourth sub-electrode 232 of the second electrode 23 by wire bonding (not shown).

The first marker 13 for the aligning with the transition substrate 21 having the laser 22 and the second marker 14 for the accurate aligning during the placing of the second lens 32 are fabricated on the surface plane 11 of the silicon photonic chip 10 (wherein both of the first marker 13 and the second marker 14 are metal alignment markers). Particularly, the transition substrate 21 is aligned with the first marker 13, filled with an ultraviolet adhesive or thermosetting adhesive, and solidified to fix the transition substrate, and then the second electrode 23 and the first electrode 12 are connected by wire bonding (not shown), so that the laser 22 and the silicon photonic chip 10 are electrically connected. The accurate positioning of the first, the second and the third markers 13, 14, 25 ensures the accurate installing of the relative positions of the laser 22 and the grating coupler 15 on the silicon photonic chip 10, thereby facilitating the subsequent optical path adjusting.

The second lens 32 is directly pasted to the silicon photonic chip 10, and its flat end surface (that is, the focal plane) closely contacts with the silicon photonic chip 10, and is fixed by the adhesive bonding by using ultraviolet adhesive, wherein the ultraviolet adhesive is a transparent adhesive (that is, transparent to the lights of the wavelength of 1.2 μm to 1.6 μm).

The supporting of the position assisting of the second marker 14 facilitates the aligning and placing of the second lens 32, so that the grating coupler 15 can be accurately positioned in the central area of the principal axis of the optical path of the second lens 32.

The position of the first lens 31 provided on the silicon photonic chip 10 may be adjusted, and thus the lights that are outputted by the laser 22 is converted into parallel light, and then an ultraviolet adhesive or thermosetting adhesive fills the gap between the first lens 31 and the silicon photonic chip 10 and is solidified.

The isolator 40 is located between the first lens 31 and the reflecting prism 50, and functions to prevent the reflected light from entering the laser 22, thereby preventing the damage to the laser 22. In the present invention, the isolator 40 may be a Faraday optical rotator.

The reflecting prism 50 is fixed to the surface plane 11, and its inclined reflecting end surface is located just above the second lens 32. The reflecting prism 50 couples parallel light beams by the second lens 32 into the grating coupler 15, and finds the optimum coupling efficiency by finely tuning the position of the second lens, and then the second lens is solidified by the ultraviolet adhesive or thermosetting adhesive. In order to obtain the optimum coupling efficiency for the grating coupler 15, the light beam incident to the grating coupler 15 has an angle inclining by designing of the reflection angle of the reflecting prism 50. Therefore, the inclination angle of the reflecting prism 50 should be between 30° and 60°.

What is claimed is:

1. A packaging structure of a laser and a grating coupler, comprising a laser unit, a collimating lens, an isolator and a reflecting prism that are provided on a silicon photonic chip,
wherein:
the silicon photonic chip comprises a surface plane and a first electrode, a first marker, a second marker, a grating coupler and a waveguide layer that are sequentially provided on the surface plane;
the laser unit comprises a transition substrate and a laser, and further comprises a second electrode that is exposed on a top surface of the transition substrate;
the collimating lens comprises a first lens and a second lens, wherein: the first lens stands perpendicularly to the surface plane with an optical path aligning with the laser, and the second lens is provided on the surface plane by aligning with the second marker, so that the grating coupler is positioned in a central area of a principal axis of an optical path of the second lens; and
the isolator is installed at a surface plane that is between the first lens and the second lens, so that a divergent light outputted by the laser is collimated by the first lens, passes through the isolator, becomes incident to the reflecting prism, is angularly deflected by the reflecting prism, and is converged by the second lens, wherein a convergence point is located at a surface of the grating coupler.

2. The packaging structure of a laser and a grating coupler according to claim 1, wherein: a solder is provided on the top surface of the transition substrate, wherein the solder is provided adjacent to a right side of the top surface, and is electrically connected to the second electrode, and the top surface that is adjacent to the solder is provided with a third marker.

3. The packaging structure of a laser and a grating coupler according to claim 2, wherein: the transition substrate is installed on the surface plane by aligning with the first marker, and the laser is fixed to the top surface by the solder when aligning with the third marker.

4. The packaging structure of a laser and a grating coupler according to claim 3, wherein: the transition substrate is formed by silicon, aluminum nitride and/or aluminum oxide.

5. A packaging method of a laser and a grating coupler according to claim 1, wherein: the method comprises:
firstly, fabricating the second electrode, a solder and the third marker on the transition substrate, and after the laser is accurately aligned with the third marker, pasting the laser to the transition substrate by the solder, wherein a top layer of the laser has a top layer electrode, and the top layer electrode is connected to the second electrode by wire bonding;
secondly, fabricating the first marker for the aligning with the transition substrate and the second marker for the accurate aligning during the placing of the second lens on the surface plane of the silicon photonic chip, wherein the second lens is directly pasted to the silicon photonic chip, in order to contact a focal plane of the second lens with the silicon photonic chip; and
by the effect of position assisting of the second marker, during the aligning and placing of the second lens, the grating coupler is located in the central area of the principal axis of the optical path of the second lens.

6. The packaging method of a laser and a grating coupler according to claim 5, wherein: the first lens can be shifted to adjusted the position on the silicon photonic chip, so that the lights outputted by the laser collimated to become parallel light, and then the first lens and the silicon photonic chip are solidified by filling ultraviolet adhesive or thermosetting adhesive.

7. The packaging method of a laser and a grating coupler according to claim 6, wherein: the isolator is located between the first lens and the reflecting prism, the reflecting prism is fixed to the surface plane, an inclined reflecting end surface of the reflecting prism is located just above the second lens, the reflecting prism couples parallel light beams by the second lens into the grating coupler, and finds a optimum coupling efficiency by finely tuning the position of the second lens, and then the second lens is solidified by filling ultraviolet adhesive or thermosetting adhesive.

8. The packaging method of a laser and a grating coupler according to claim 7, wherein: an optimum coupling efficiency of the grating coupler is obtained by adjusting the second lens and by varying an angle of the reflecting prism, wherein: an angle of a light beam incident to the grating coupler from the reflecting prism is between 30° and 60°.

9. The packaging method of a laser and a grating coupler according to claim 8, wherein: the transition substrate is pasted by aligning with the first marker and then solidified by filling ultraviolet adhesive or thermosetting adhesive, and simultaneously the second electrode and the first electrode are electrically connected by wire bonding, so that the laser and the silicon photonic chip are electrically connected.

10. The packaging method of a laser and a grating coupler according to claim 9, wherein: the ultraviolet adhesive or thermosetting adhesive is a transparent adhesive, and the transparent adhesive solidified on the packaging structure of the laser and the grating coupler is transparent to lights of wavelength of 1.2 μm to 1.6 μm.
